(19) United States
(12) Patent Application Publication
(10) Pub. No.: US 2011/0199141 A1
(43) Pub. Date: Aug. 18, 2011

(54) PHASE SHIFTER AND CONTROL METHOD THEREOF

(75) Inventors: Donghwan Shin, Daejon (KR); Changsoo Kwak, Daejon (KR); So-Hyeun Yun, Daejon (KR); In-Bok Yom, Daejon (KR)

(73) Assignee: ELECTRONICS AND TELECOMMUNICATIONS RESEARCH INSTITUTE, Daejon (KR)

(21) Appl. No.: 13/124,141

(22) PCT Filed: Sep. 15, 2009
(86) PCT No.: PCT/KR2009/005238

§ 371 Date: Apr. 14, 2011

(30) Foreign Application Priority Data
Oct. 24, 2008 (KR) 10-2008-0104838

(51) Int. Cl. H03H 11/20

(52) U.S. Cl. 327/252

(57) ABSTRACT

Provided is a phase shifter having a high phase difference in a microwave band. The phase shifter includes a first phase shifting unit configured to receive an input signal having a predetermined frequency, receive a first control signal and a second control signal operating contrary to the first control signal, output the input signal as it is when the first control signal is activated, and output the input signal to have a lead phase as much as a predetermined phase, and a second phase shifting unit configured to receive a second signal outputted from the first phase shifting unit, receive the first control signal and the second control signal, output the second signal to have a lagged phase as much as a predetermined phase when the first control signal is activated, and output the second signal as it is when the second control signal is activated.

### TECHNICAL FIELD

The present invention relates to a phase shifter; and, more particularly, to a phase shifter having a high phase difference in a microwave frequency band.

### BACKGROUND ART

Phase shifters are used to change a phase of a desired signal in a wireless communication system. The phase shifters have been widely used in various fields related to a wireless communication system. For example, a phase shifter is used to control a beam emission direction of an array antenna such as a smart antenna or a radar system.

Hereinafter, a phase shifter will be described in detail. The phase shifter is an essential element for controlling a beam direction of an antenna in a phase array antenna or a radar system. Phase shifters can be broadly classified as mechanical or electronic, depending on whether the phase control is achieved through mechanical or electronic tuning. Depending on the type of operation, phase shifters can be categorized as analog or digital. Among them, a small-size digital phase shifter employing a monolithic microwave integrated chip (MMIC) technology has been widely used due to the following reason. A phase array antenna or a radar system includes more than hundreds of radiation elements. In order to control the radiation elements, the phase array antenna or the radar system should include the phase shifters as many as the radiation elements.

The MMIC digital phase shifter has been designed as a switched line type or a switched filter type. In the switched line type digital phase shifter, phase shift is obtained by switching the signal between the two different path by switches formed of a metal semiconductor field effect transistor (MESFET) or a high electron mobility transistor (HEMT). In the switched filter type digital phase shifter, phase shift is obtained by switching between high-pass section and low-pass section which is composed of passive inductors and capacitors or taking into account of MESFET (or HEMT) parameters as part of the high-pass or low-pass filter network.

Lately, a phase array antenna and a radar system require 5 to 7 bits as a phase bit of a digital phase shifter. Therefore, the phase array antenna and the radar system require the phase shifters as many as the number of phase bits. Since the switched filter type digital phase shifter can be embodied in a small size, the switched filter type digital phase shifter has been widely used. However, it is difficult to realize a switched filter type digital phase shifter having a high phase difference such as 90° or 180° in a small size.

FIG. 1 is a circuit diagram illustrating a phase shifter according to the prior art.

The phase shifter of FIG. 1 is generally used as a phase shifter having a high phase difference such as 90° and 180°. As shown in FIG. 1, the phase shifter includes six GaAs FET switches 131, 132, 133, 141, 142, and 143, two capacitors 151 and 152, and four inductors 161, 162, 163, and 164. The six GaAs FET switches 131, 132, 133, 141, 142, and 143 are both switching elements and filter elements at the same time. In order to make a high phase difference, the phase shifter operates as a high pass filter or as a low pass filter when two pairs of three FETs are turned on and off alternately according to variation of a control voltage applied to first and second control terminals 170 and 180. To be specific, FETs 131, 132, 133, 141, 142, and 143 may become equivalent to a resistor having a low value when the FETs are turned on according to the variation of the control voltage. The FETs 131, 132, 133, 141, 142, and 143 may become equivalent to a capacitor when the EFTs are turned off according to the variation of the control voltage. If the FETs 131, 132, and 133 are turned off by the first control terminal 180 and if the FET 141, 142, and 143 are turned on by the second terminal 170, a typical phase shifter becomes equivalent to a 5^{th} order low pass filter. Accordingly, the typical phase shifter outputs the input signal with a lagged phase. On the contrary, if the FETs 131, 132, and 133 are turned on by the first control terminal 180 and if the FET 141, 142, and 143 are turned off by the second terminal 170, a typical phase shifter becomes equivalent to a 5^{th} high pass filter. Accordingly, the typical phase shifter outputs the input signal with a lead phase. Since such a typical phase shifter needs 6 FET elements, it is difficult to reduce the size thereof and to simply the structure thereof. Since the phase shifter includes a lot of elements, the cost thereof is high too.

### DISCLOSURE

### Technical Problem

An embodiment of the present invention is directed to providing a phase shifter having a high phase difference and having a small size and a control method thereof.

Another embodiment of the present invention is directed to providing a phase shifter having a high phase difference and requiring less manufacturing cost and a control method thereof.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided a phase shifter including a first phase shifting unit configured to receive an input signal having a predetermined frequency, receive a first control signal and a second control signal operating contrary to the first control signal, output the input signal as it is when the first control signal is activated, and output the input signal to have a lead phase as much as a predetermined phase, and a second phase shifting unit configured to receive a second signal outputted from the first phase shifting unit, receive the first control signal and the second control signal, output the second signal to have a lagged phase as much as a predetermined phase when the first control signal is activated, and output the second signal as it is when the second control signal is activated.

In accordance with another aspect of the present invention, there is provided a method for controlling a phase shifter that receives a first control signal and a second control signal operating contrary to the first control signal and changes a phase of an input signal, including receiving the input signal having a predetermined frequency, outputting the input signal as it is in response to the first control signal at a first phase shifting, and changing an output of the first phase shifting unit to have a lagged phase as much as predetermined phase in response to the second control signal at the second phase shifting unit.

In accordance with another aspect of the present invention, there is provided a method of controlling a phase shifter that receives a first control signal and a second control signal operating contrary to the first control signal and changes a phase of an input signal, including receiving the input signal having a predetermined frequency, changing the input signal to have a lead phase as much as a predetermined phase in response to the second control signal at a first phase shifting unit, and outputting an output of the first phase shifting unit as it is in response to the first control signal at the second phase shifting unit.

### Advantageous Effects

A phase shifter according to the present invention can be simplified and reduced in size. Also, the phase shifter according to the present invention requires less manufacturing cost.

### BRIEF DESCRIPTION OF THE DRAWINGS

FIG. 1 is a circuit diagram illustrating a phase shifter according to the prior art.

FIG. 2 is a circuit diagram illustrating a phase shifter in accordance with an embodiment of the present invention.

FIGS. 3 and 4 are circuit diagrams illustrating a phase shifter shown in FIG. 2.

FIG. 5 is a picture showing a MMIC phase shifter having a C-band 180° in accordance with an embodiment of the present invention.

FIG. 6 is a graph showing S-parameters of a phase shifter in accordance with an embodiment of the present invention.

FIG. 7 is a graph showing phase-variation characteristics of a phase shifter in accordance with an embodiment of the present invention.

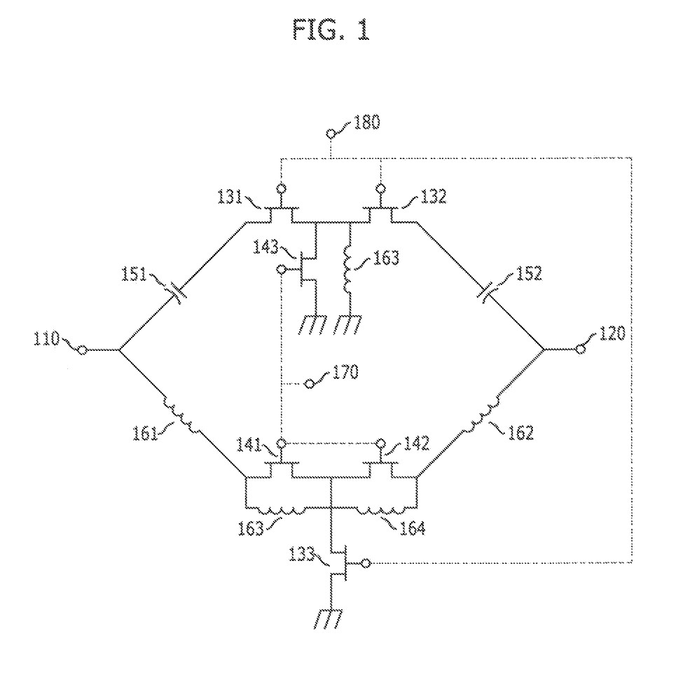

### BEST MODE FOR THE INVENTION

The advantages, features and aspects of the invention will become apparent from the following description of the embodiments with reference to the accompanying drawings, which is set forth hereinafter.

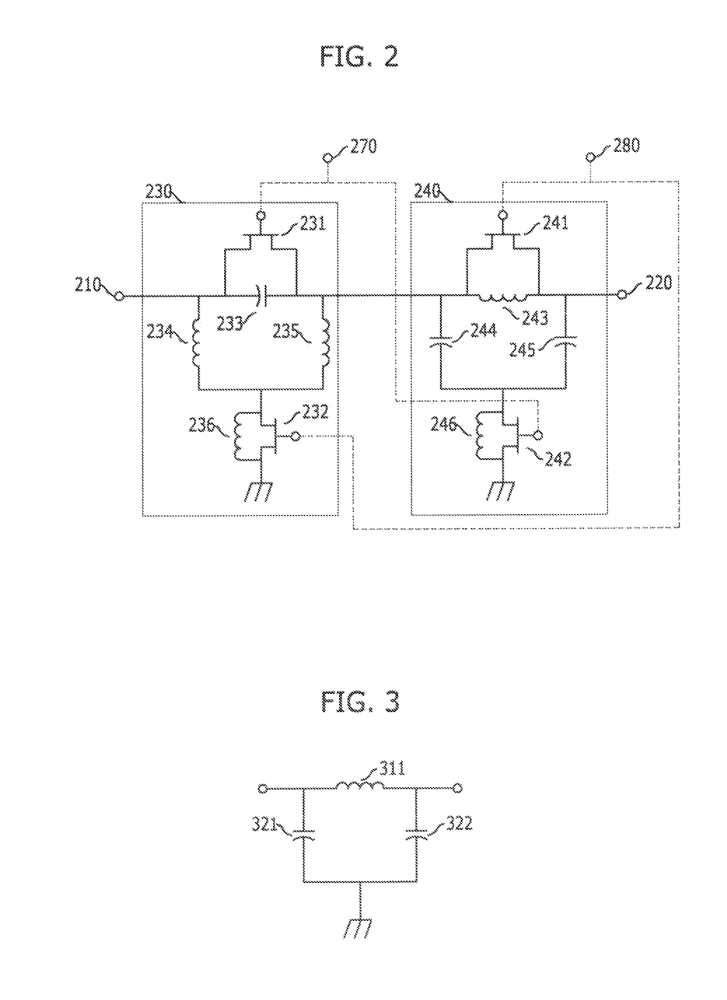

FIG. 2 is a circuit diagram illustrating a phase shifter in accordance with an embodiment of the present invention.

Referring to FIG. 2, the phase shifter according to the present embodiment includes a first phase shifting unit 230 and a second phase shifting unit 240.

The first phase shifting unit 230 receives an input signal having a predetermined frequency, a first control signal, and a second control signal. Here, the second control signal operates contrary to the first control signal. The first phase shifting unit 230 outputs an input signal as it is when the first control signal is activated. On the contrary, the first phase shifting unit 230 changes the input signal to have a phase lead as much as a predetermined phase when the second control signal is activated. Such a first phase shifting unit 230 includes a first switch 231, a second switch 232, a first capacitor 233, a first inductor 234, a second inductor 235, and a third inductor 236. The first and second switches 231 and 232 may be embodied using a Field Effect Transistor (FET), a Metal Semiconductor Field Effect Transistor (MESFET), or a High Electron Mobility Transistor (HEMT). Among them, the HEMT is preferably used to form the switches. The first capacitor 233 is connected to a drain terminal and a source terminal of the first switch in parallel. The first and second inductors 234 and 235 are connected to each other in serial and connected to both ends of the first capacitor 233. The third inductor 236 is connected to a drain terminal and a source terminal of the second switch 232 in parallel. The second switch 232 has one end connected between the first and second inductors and the other end connected to the ground.

The second phase shifting unit 240 receives a second signal outputted from the first phase shifting unit 230 and receives first and second control signals. When the first control signal is activated, the second phase shifter 240 shifts the second signal to have a phase lagged as much as a predetermined phase. When the second control signal is activated, the second phase shifter 240 outputs the second signal as it is. Such a second phase shifting unit 240 includes a third switch 241, a fourth switch 242, a fourth inductor 243, a second capacitor 244, a third capacitor 245, and a fifth inductor 262. The third and fourth switches 241 and 242 may be embodied using FET, MESFET, or HEMT. Among them, the HEMT is preferable to use for forming the switch. The fourth inductor 243 is connected to a drain terminal and a source terminal of the third switch 241 in parallel, and the second and third capacitors 244 and 245 are connected to each other in serial, thereby being connected to both ends of the fourth inductor 243 in parallel. The fifth inductor 246 is connected to the fourth switch 242 in parallel. The fourth switch 242 includes one end connected between the second and third capacitors 244 and 245 and the other end connected to the ground.

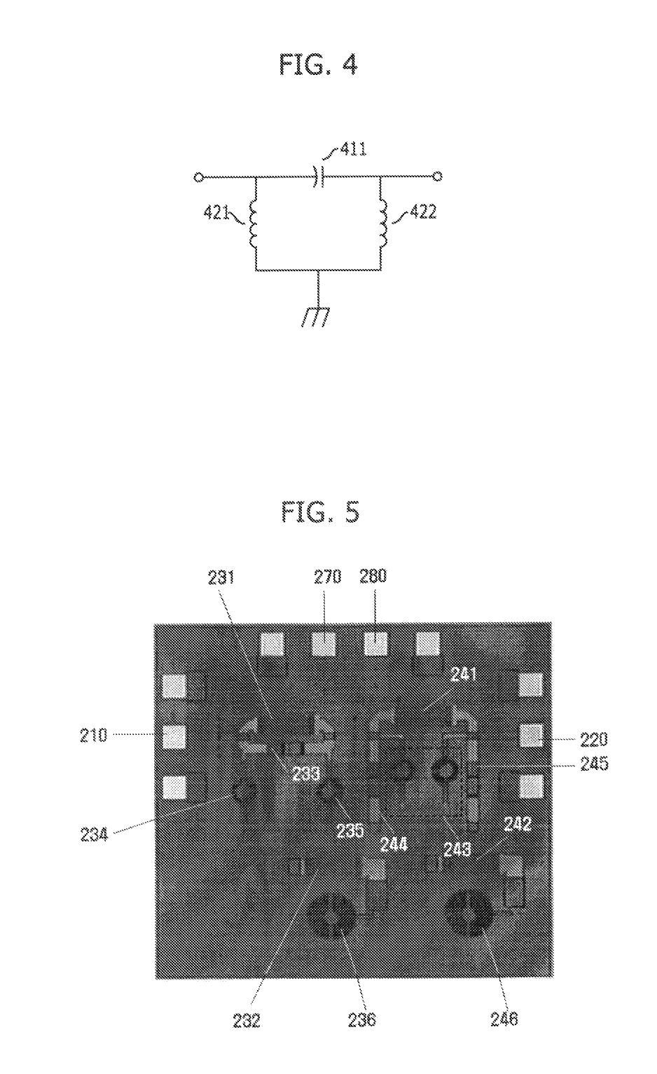

Hereinafter, the operation and the control method of the phase shifter shown in FIG. 2 will be described with reference to FIGS. 3 and 4.

FIGS. 3 and 4 illustrate a circuit diagram of a phase shifter in accordance with an embodiment of the present invention.

As shown in FIGS. 3 and 4, the first to fourth switches 231, 232, 241, and 242 are controlled to be turned on/off by a first control signal applied to the first control terminal 270 and a second control signal applied to the second control terminal 280. The first control signal is a signal activating the first to fourth switches 231, 232, 241, and 242, and the second control signal is a signal inactivating the first to fourth switches 231, 232, 241, and 242. The first switch 231 and the fourth switch 242 operate together by the first control signal or the second control signal. Also, the second switch 232 and the third switch 241 operate together by the first control signal or the second control signal.

At first, when the first and fourth switches 231 and 242 are turned on by the first control signal and the second and third switches 232 and 241 are turned off by the second control signal, the operation of the phase shifter will be described.

When the first phase shifter 230 receives an input signal, the first switch 231 becomes a typical line having a low resistance value smaller than an impedance value of the first capacitor, and the second switch 232 becomes equivalent to the capacitor. Also, when an impedance value is set to make the third inductor 236 and the second switch 232 to be parallel-resonant, the impedance in a view from the first and second inductors 234 and 235 to the circuit becomes infinity. Therefore, the first and second inductors 234 and 235 can be ignored because the first and second inductors 234 and 235 influence the overall circuit very slightly. Finally, since the first phase shifting unit 230 including the first and second switches 231 and 232 operate as a typical line, the first phase shifting 230 outputs the input signal having a predetermined frequency as it is.

The second phase shifting unit 240 receives a second signal outputted from the first phase shifting unit 230. Since the third switch 241 is turned off, the second phase shifter 240 becomes equivalent to a capacitor. If the impedance of the capacitor is set to be greater than the impedance of the fourth inductor 243, the second phase shifting unit 240 and the third switch 241 become equivalent to the inductor 311 in FIG. 3. The second capacitor 244 becomes equivalent to the capacitor 321 of FIG. 3, and the third capacitor 245 becomes equivalent to the capacitor 322 of FIG. 2. Since the fourth switch 242 becomes a typical line having a small resistance value, it becomes equivalent to the capacitors 321 and 322 of FIG. 2 directly connected to the ground. Finally, the phase shifter having the first phase shifting unit 230 and the second phase shifting unit 240 becomes equivalent to a low pass filter as shown in FIG. 3. Since the low pass filter makes a phase of an input signal to be lagged, the phase shifter according to the present embodiment outputs an input signal with a phase lagged compared that of the input signal.

Hereinafter, when the first and fourth switches 231 and 242 are turned off by the first control signal and when the second switch 232 and the third switch 241 are turned on by the second control signal, the operation of the phase shifter will be described.

The first switch 231 of the first phase shifting unit 230 becomes equivalent to a capacitor. Therefore, the first switch 231 becomes equivalent to the capacitor 411 of FIG. 4 with the first capacitor 233. The first inductor 234 becomes equivalent to the inductor 421 of FIG. 4, and the second inductor 235 becomes equivalent to the inductor 422 of FIG. 4. Since the second switch 232 becomes equivalent to a typical line having a small resistance value, the second switch 232 becomes equivalent to the inductors 421 and 422 of FIG. 4 directly connected to a ground. Finally, the phase shifter including the first and second phase shifting units 230 and 240 according to the present embodiment becomes equivalent to a high pass filter. Since the high pass filter makes a phase of a signal to be led, the phase shifter according to the present embodiment outputs a signal having a lead phase compared to a phase of an input signal.

The phase shifter according to the present embodiment shown in FIG. 2 becomes equivalent to the low pass filter or the high pass filter by the first and second control signals as shown in FIGS. 3 and 4. Therefore, the phase shifter according to the present embodiment generates a phase difference of an input signal. For example, if it is required to generate a phase difference of Φ, a low pass filter circuit generates a phase difference of −Φ/2, and a high pass filter circuit generates a phase difference of Φ/2. The capacitance of the capacitors 321, 322, and 411 and the inductance of the inductors 311, 421, and 422 shown in FIGS. 3 and 4 can be defined by Eq. 1.

$$L ( 311 ) = {Z}_{0} \frac{sin ( ϕ )}{ω} [ H ] , C ( 321 , 322 ) = \frac{1 - cos ( ϕ )}{ω {Z}_{0} sin ( ϕ )} [ F \} \\ C ( 411 ) = \frac{1}{ω {Z}_{0} sin ( ϕ )} [ F ] , L ( 421 , 422 ) = \frac{{Z}_{0} sin ( ϕ )}{ω ( 1 - cos ( ϕ ) )} [ H ] \\ Where ϕ = φ / 2 [ radian ] . \qquad Eq . 1$$

FIG. 5 is a picture showing a MMIC phase shifter having a C-band 180° in accordance with an embodiment of the present invention. Like numeral references denote like elements in FIGS. 2 and 5.

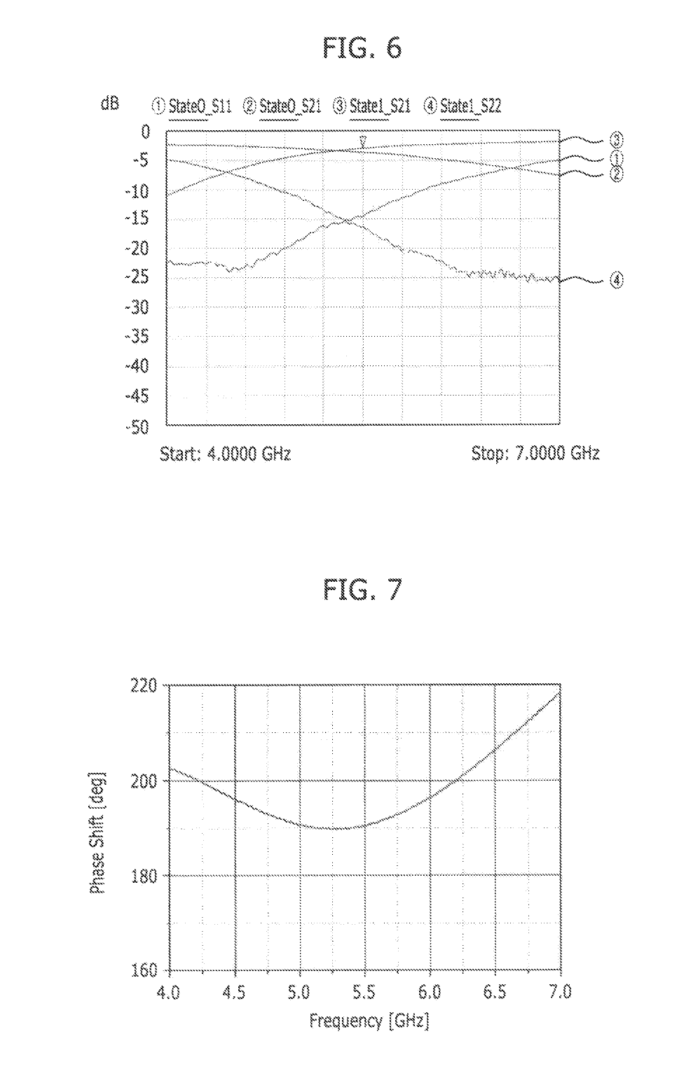

FIG. 6 is a graph showing S-parameter characteristics of a phase shifter in accordance with an embodiment of the present invention.

In the graph, a state 0 denotes a state of a phase shifter when the first switch 231 and the fourth switch 242 are turned on in FIG. 2. A state 1 denotes a state of a phase shifter when the first switch 231 and the fourth switch 242 are turned off and the second switch 232 and the third switch 242 are turned on. A graph \textcircled{1} shows reflection coefficient S11 and a graph \textcircled{2} shows S21 when the phase shifter according to the present embodiment becomes equivalent to a low pass filter circuit at the state 0. A graph \textcircled{3} shows S21 and a graph \textcircled{4} shows reflection coefficient S22 because the phase shifter according to the present embodiment operates as a high pass filter circuit.

FIG. 7 is a graph showing phase variation character of a phase shifter in accordance with an embodiment of the present invention.

As shown in FIG. 7, a phase difference between the state 0 and the state 1 is about 190°. Since an error of about 10° can be adjusted by controlling capacitance and inductance, it is possible to design a phase shifter having a high phase difference such as 180°. Therefore, the phase shifter according to the present embodiment can shift the input signal to have a high phase difference of about 180° only using four switch elements.

The present application contains subject matter related to Korean Patent Application No. 10-2008-0104838, filed in the Korean Intellectual Property Office on Oct. 24, 2008, the entire contents of which is incorporated herein by reference.

While the present invention has been described with respect to the specific embodiments, it will be apparent to those skilled in the art that various changes and modifications may be made without departing from the spirit and scope of the invention as defined in the following claims.

What is claimed is:

1. A phase shifter, comprising:
a first phase shifting unit configured to receive an input signal having a predetermined frequency, receive a first control signal and a second control signal operating contrary to the first control signal, output the input signal as it is when the first control signal is activated, and output the input signal to have a lead phase as much as a predetermined phase; and
a second phase shifting unit configured to receive a second signal outputted from the first phase shifting unit, receive the first control signal and the second control signal, output the second signal to have a lagged phase as much as a predetermined phase when the first control signal is activated, and output the second signal as it is when the second control signal is activated.

2. The phase shifter of claim 1, wherein the first phase shifter includes:
a first switch configured to pass the input signal as it is by being activated by the first control signal; and
a second switch configured to control the input signal to have a lead phase as much as a predetermined phase by being activated by the second control signal.

3. The phase shifter of claim 2, wherein the first phase shifting unit includes:
a first capacitor connected to the first switch in parallel;
first and second inductors connected to each other in serial and connected to both ends of the first capacitor in parallel; and
a third inductor connected to the second switch in parallel,
wherein the second switch includes one end connected between the first and second inductors and the other end connected to the ground.

4. The phase shifter of claim 3, wherein when the first switch is activated by the first control signal, an impedance of the first switch is smaller than an impedance of the first capacitor.

5. The phase shifter of claim 4, wherein when the second switch is inactivated by the second control signal, the second switch and the third inductor become parallel-resonant.

6. The phase shifter of claim 1, wherein the second phase shifting unit includes:
a third switch configured to pass the second signal as it is by being activated by the second control signal and; and
a fourth switch configured to control the second signal to have a phase lagged as much as a predetermined phase by being activated by the first control signal.

7. The phase shifter of claim 6, wherein the second phase shifting unit includes:
a fourth inductor connected to the third switch in parallel;
second and third capacitors connected to each other in serial and connected to both ends of the fourth inductor in parallel; and
a firth inductor connected to the fourth switch in parallel,
wherein the fourth switch includes one end connected between the second and third capacitors and the other end connected to a ground.

8. The phase shifter of claim 7, wherein when the third switch is inactivated by the second control signal, the third switch and the fourth inductor become equivalent to a capacitor.

9. The phase shifter of claim 8, wherein when the fourth switch is activated by the first control signal, an impedance of the fourth switch is smaller than an impedance of the fifth inductor.

10. A method of controlling a phase shifter that receives a first control signal and a second control signal operating contrary to the first control signal and changes a phase of an input signal, comprising:
receiving the input signal having a predetermined frequency;
outputting the input signal as it is in response to the first control signal at a first phase shifting; and
changing an output of the first phase shifting unit to have a phase lagged as much as predetermined phase in response to the second control signal at the second phase shifting unit.

11. A method of controlling a phase shifter that receives a first control signal and a second control signal operating contrary to the first control signal and changes a phase of an input signal, comprising:
receiving the input signal having a predetermined frequency;
changing the input signal to have a phase led as much as a predetermined phase in response to the second control signal at a first phase shifting unit; and
outputting an output of the first phase shifting unit as it is in response to the first control signal at the second phase shifting unit.
